(19) United States
(12) Patent Application Publication
(10) Pub. No.: US 2025/0338575 A1
(43) Pub. Date: Oct. 30, 2025

(54) SEMICONDUCTOR STRUCTURE WITH GATE ISOLATION LAYER AND MANUFACTURING METHOD THEREOF

(71) Applicant: Taiwan Semiconductor Manufacturing Co., Ltd., Hsinchu (TW)

(72) Inventors: Chun-Yu Liu, New Taipei City (TW); Tsung-Kai Chiu, Zhubei City (TW); Shao-Tse Huang, Hsinchu City (TW); Szu-Hua Chen, Tainan City (TW); Ku-Feng Yang, Baoshan Township (TW); Szuya Liao, Zhubei (TW)

(21) Appl. No.: 19/258,257

(22) Filed: Jul. 2, 2025

Related U.S. Application Data
(63) Continuation of application No. 18/603,046, filed on Mar. 12, 2024.
(60) Provisional application No. 63/620,304, filed on Jan. 12, 2024.

(51) Int. Cl. H10D 62/10; H10D 30/01; H10D 30/43; H10D 30/67; H10D 84/01; H10D 84/03; H10D 84/85

(52) U.S. Cl. CPC H10D 62/121; H10D 30/014; H10D 30/43; H10D 30/6735; H10D 30/6757; H10D 84/0167; H10D 84/017; H10D 84/038; H10D 84/85

(57) ABSTRACT

A method includes forming a lower semiconductor region, forming an upper semiconductor region overlapping the lower semiconductor region, forming a lower gate dielectric and an upper gate dielectric on the lower semiconductor region and the upper semiconductor region, respectively, forming a lower gate electrode on the lower gate dielectric and the upper gate dielectric, etching back the lower gate electrode, forming a gate isolation layer on the lower gate electrode that has been etched back, and forming an upper gate electrode over the gate isolation layer. The upper gate electrode is on the upper gate dielectric.

### PRIORITY CLAIM AND CROSS-REFERENCE

This application is a continuation of U.S. patent application Ser. No. 18/603,046, filed on Mar. 12, 2024, which application claims the benefit of the following provisionally filed U.S. Patent application: Application No. 63/620,304, filed on Jan. 12, 2024, and entitled “Semiconductor Structure with Gate Isolation Layer and Manufacturing Method Thereof,” which applications are hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the minimum feature sizes are reduced, however, additional problems arise and should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of example Complementary Field-Effect Transistors (CFETs) in accordance with some embodiments.

FIGS. 2 through 7A, 7B, 8A, 8B, 9-13, 14A, 14B, and 14C are views of intermediate stages in the manufacturing of CFETs in accordance with some embodiments.

FIGS. 15-22 are views of intermediate stages in the manufacturing of CFETs in accordance with some embodiments.

FIG. 23 illustrates a perspective view of a CFET structure in accordance with some embodiments.

FIG. 24 illustrates a flow chart for forming CFETs in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A Complementary Field-Effect Transistor (CFET) structure and the method of forming the same are provided. Throughout the description, the terms “FET” and “transistor” are used interchangeably. In accordance with some embodiments, A CFET structure includes a lower FET and an upper FET overlapping the lower FET. A gate dielectric isolation layer is formed over the gate electrode of the lower FET and under the gate electrode of the upper FET. Accordingly, the gate electrode of the lower FET is electrically isolated from the gate electrode of the upper FET.

It is appreciated that while Gate-All-Around (GAA) transistors (such as nanostructure-FETs) are discussed as an example, the concept of the present disclosure can also be applied to the formation of other types of transistors such as planar transistors, Fin Field-Effect Transistors (FinFETs), or the like.

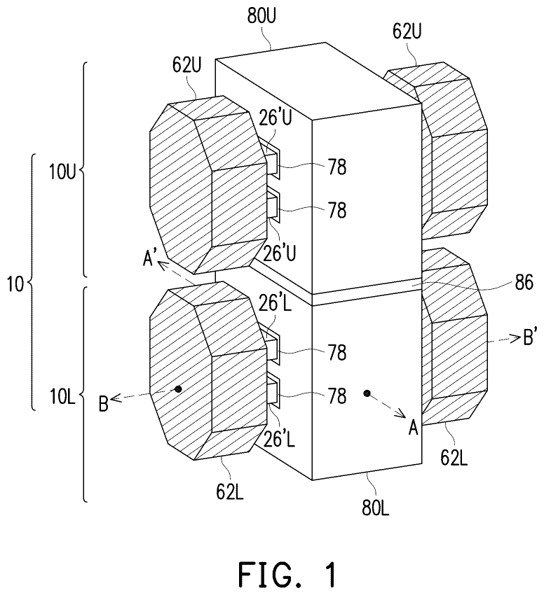

FIG. 1 illustrates an example of CFETs 10 (including FETs (transistors) 10U and 10L) in accordance with some embodiments. FIG. 1 is a three-dimensional view, wherein some features of the CFETs are omitted for illustration clarity.

A CFET 10 may include a lower nanostructure-FET 10L of a first device type (e.g., n-type/p-type) and an upper nanostructure-FET 10U of a second device type (e.g., p-type/n-type) that is opposite the first device type. The nanostructure-FETs 10U and 10L include semiconductor nanostructures 26′ (including lower semiconductor nanostructures 26′L and upper semiconductor nanostructures 26′U), where the semiconductor nanostructures 26′ act as the channel regions for the nanostructure-FETs. The lower semiconductor nanostructures 26′L are for the lower nanostructure-FET 10L, and the upper semiconductor nanostructures 26′U are for the upper nanostructure-FET 10U.

Gate dielectrics 78 encircle the respective semiconductor nanostructures 26′. Gate electrodes 80 (including a lower gate electrode 80L and an upper gate electrode 80U) are on the gate dielectrics 78. Source/drain regions 62 (including lower source/drain regions 62L and upper source/drain regions 62U) are disposed on opposing sides of the gate dielectrics 78 and the respective gate electrodes 80. The source/drain region may refer to a source or a drain, individually or collectively dependent upon the context. Isolation features (not shown) may be formed to separate desired ones of the source/drain regions 62 and/or desired ones of the gate electrodes 80.

FIG. 1 further illustrates reference cross-sections that are used in later figures. Cross-Cross-section A-A′ is a vertical cross-section that is perpendicular to cross-section A-A′ and along a longitudinal axis of a gate electrode 80 of the CFET. section B-B′ is a vertical cross-section that is parallel to a longitudinal axis of the semiconductor nanostructures 26′ of a CFET and in a direction of, for example, a current flow between the source/drain regions 62 of the CFET. Subsequent figures may refer to these reference cross-sections for clarity.

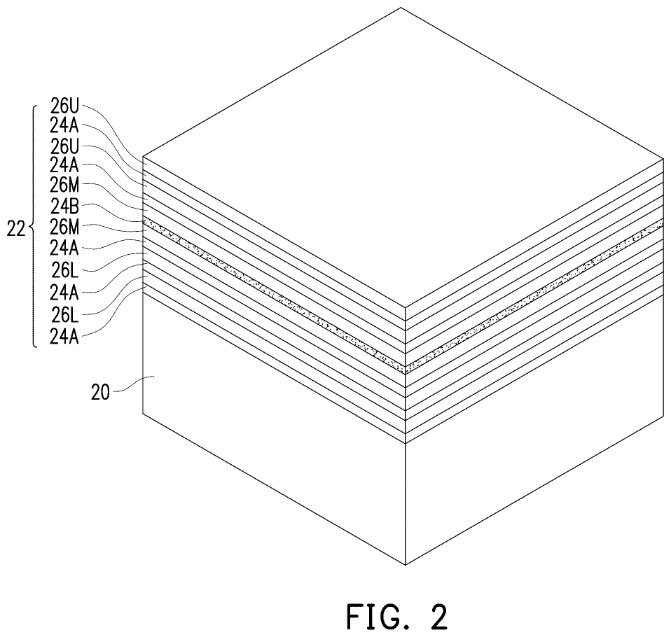

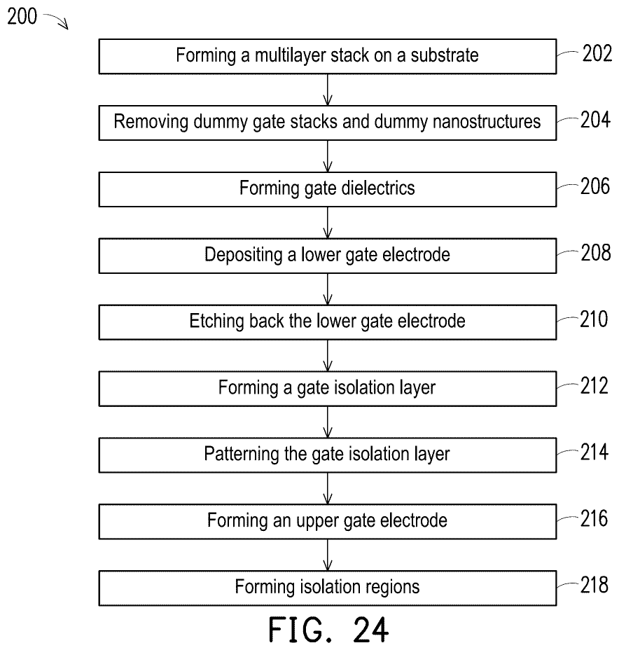

FIGS. 2 through 14A, 14B, and 14C illustrate the cross-sectional views of intermediate stages in the formation of CFETs (as schematically represented in FIG. 1) in accordance with some embodiments. The corresponding processes are also reflected schematically in the process flow 200 as shown in FIG. 24.

In FIG. 2, wafer 2, which includes substrate 20, is provided. Substrate 20 may be a semiconductor substrate, such as a bulk semiconductor, a semiconductor-on-insulator (SOI) substrate, or the like, which may be doped (e.g., with a p-type or an n-type dopant) or undoped. The SOI substrate may include a layer of a semiconductor material formed on an insulator layer. The insulator layer may be, for example, a buried oxide (BOX) layer, a silicon oxide layer, or the like. The insulator layer is provided on a substrate, such as a silicon or glass substrate. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

A multi-layer stack 22 is formed over the substrate 20. The multi-layer stack 22 includes alternating dummy semiconductor layers 24 (including dummy semiconductor layers 24A and a dummy semiconductor layer 24B) and semiconductor layers 26 (including lower semiconductor layers 26L and upper semiconductor layers 26U). Lower semiconductor layers 26L and upper semiconductor layers 26U are for forming a lower FET and an upper FET, respectively.

Appropriate wells (not separately illustrated) may be formed in lower semiconductor layers 26L and upper semiconductor layers 26U. For example, semiconductor layers 26L and 26U may be in-situ doped (when epitaxially grown) and/or implanted to desirable conductivity types.

In the illustrated example, the multi-layer stack 22 includes six of the dummy semiconductor layers 24 and six of the semiconductor layers 26. It should be appreciated that the multi-layer stack 22 may include any number of the dummy semiconductor layers 24 and the semiconductor layers 26. Each layer of the multi-layer stack 22 may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like.

The dummy semiconductor layers 24A are formed of a first semiconductor material, the dummy semiconductor layer 24B is formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor layers 26 (including the lower semiconductor layers 26L and upper semiconductor layers 26U) are formed of one or more semiconductor material(s). The semiconductor material(s) may be selected from the candidate semiconductor materials of the substrate 20. The lower semiconductor layers 26L and the upper semiconductor layers 26U may be formed of the same semiconductor material, or may be formed of different semiconductor materials.

In some embodiments, dummy semiconductor layers 24A are formed of or comprise silicon germanium, semiconductor layers 26 are formed of silicon, and dummy semiconductor layer 24B may be formed of germanium or silicon germanium that has a higher germanium atomic percentage than in semiconductor layer 24A.

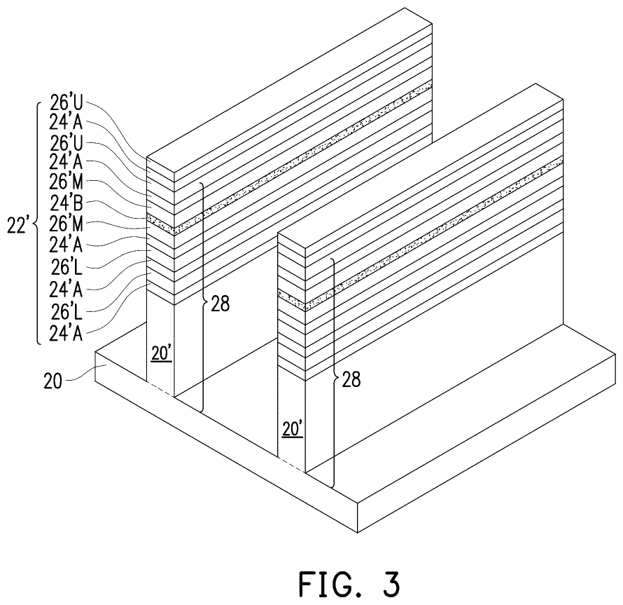

In FIG. 3, multi-layer stack 22 and substrate 20 are patterned to form semiconductor strips 28. The respective process is illustrated as process 202 in the process flow 200 as shown in FIG. 24. Each of semiconductor strips 28 includes semiconductor strip 20′ (the portions of the original substrate 20) and multi-layer stack 22′, which is the remaining portion of multi-layer stack 22. The remaining portions 22′ of multi-layers stack 22 are referred to as nanostructures hereinafter, which are referred to using the corresponding reference number followed by a “ ” sign. Accordingly, multi-layer stack 22′ includes dummy nanostructures 24′A, dummy nanostructures 24′B, lower semiconductor nanostructures 26′L, middle semiconductor nanostructures 26′M, and upper semiconductor nanostructures 26′U. The etching may be performed by any acceptable etch process, such as a Reactive Ion Etch (RIE), Neutral Beam Etch (NBE), the like, or a combination thereof. The etching may be anisotropic. Dummy nanostructures 24′A and dummy nanostructures 24′B may further be collectively referred to as dummy nanostructures 24′. The lower semiconductor nanostructures 26′L and the upper semiconductor nanostructures 26′U may further be collectively referred to as semiconductor nanostructures 26′.

The lower semiconductor nanostructures 26′L will act as channel regions for lower nanostructure-FETs of the CFETs. The upper semiconductor nanostructures 26′U will act as channel regions for upper nanostructure-FETs of the CFETs. The middle semiconductor nanostructures 26′M are the semiconductor nanostructures 26′ that are immediately above/below (e.g., in contact with) the dummy nanostructures 24′B. The middle semiconductor nanostructures 26′M may be used for isolation and may or may not act as channel regions for the CFETs. The dummy nanostructures 24′B will be subsequently replaced with isolation structures. The isolation structures and the middle semiconductor nanostructures 26′M may define boundaries of the lower nanostructure-FETs and the upper nanostructure-FETs.

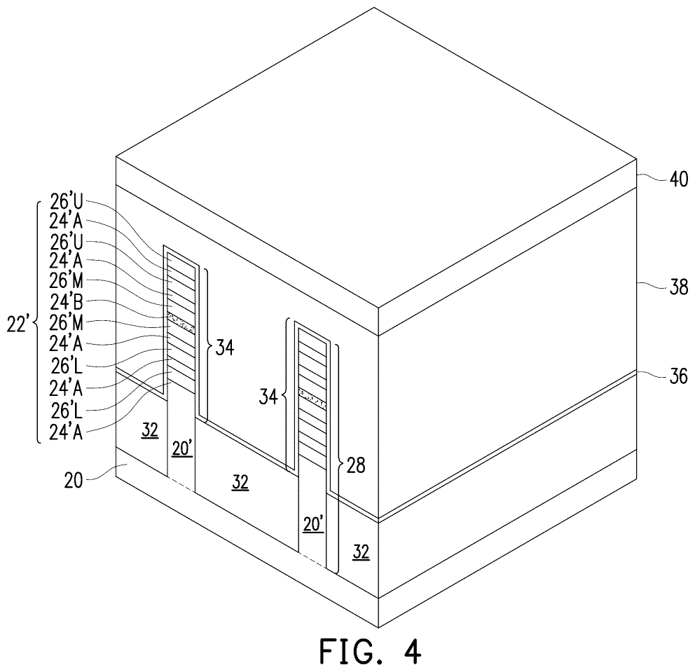

In FIG. 4, isolation regions 32 are formed over the substrate 20 and between adjacent semiconductor strips 28. Isolation regions 32 may include a dielectric liner and a dielectric material over the dielectric liner.

Isolation regions 32 are then recessed. Some upper portions of semiconductor strips 28 (including multi-layer stacks 22′) protrude higher than the remaining isolation regions 32 to form protruding fins 34.

Dummy dielectric layer 36 is then formed on the protruding fins 34. Dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a Chemical Mechanical Polish (CMP) process. The material of dummy gate layer 38 be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like.

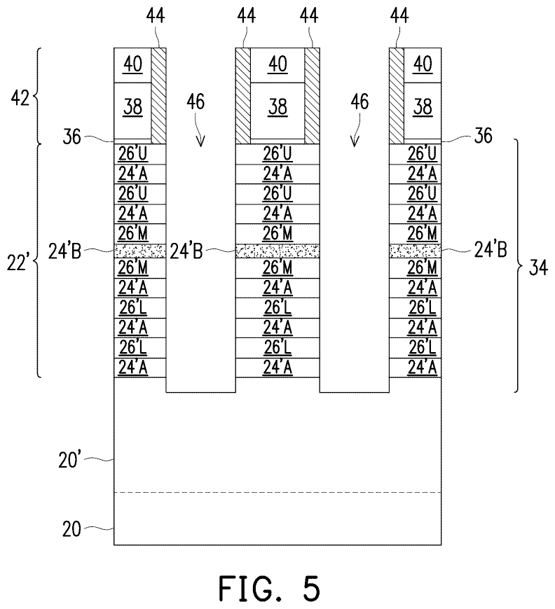

Next, the mask layer 40 may be patterned through photolithography and etching processes to form a mask, which is then used to etch and pattern dummy gate layer 38, and possibly dummy dielectric layer 36. A resulting structure is shown in FIG. 5. The remaining portions of mask layer 40, dummy gate layer 38, and dummy dielectric layer 36 form dummy gate stacks 42.

In FIG. 5, gate spacers 44 are formed over the multi-layer stacks 22′ and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers 45 are also formed.

Source/drain recesses 46 are then formed in semiconductor strips 28. The source/drain recesses 46 are formed through etching, and may extend through the multi-layer stacks 22′ and into the semiconductor strips 20′. The bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon source/drain recesses 46 reaching a desired depth.

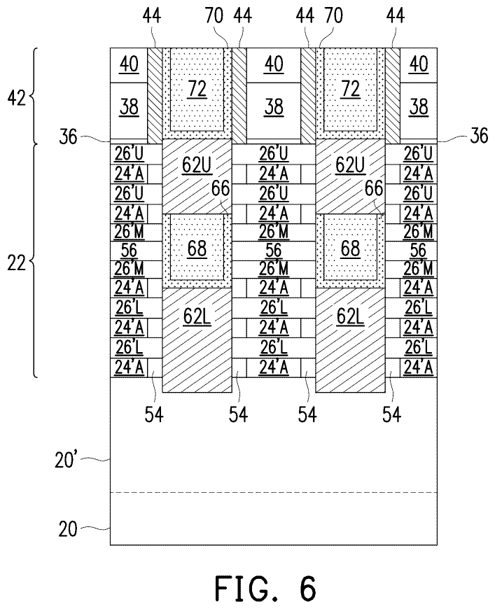

In a subsequent process, dummy nanostructures 24′A are laterally recessed, and a dielectric material is filled into the respective recesses to form inner spacers 54, which are dielectric spacers. The resulting structure is shown in FIG. 6. Also, dummy nanostructures 24′B are also removed, and are filled with a dielectric material to form dielectric isolation layers 56.

Next, lower epitaxial source/drain regions 62L are formed in the lower portions of the source/drain recesses 46 (FIG. 5). The lower epitaxial source/drain regions 62L are in contact with the lower semiconductor nanostructures 26′L and are not in contact with the upper semiconductor nanostructures 26′U. Inner spacers 54 electrically insulate the lower epitaxial source/drain regions 62L from the dummy nanostructures 24′A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants.

A first contact etch stop layer (CESL) 66 and a first ILD 68 are formed. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26′U are exposed.

Next, upper epitaxial source/drain regions 62U are formed in the upper portions of the source/drain recesses 46. The materials of upper epitaxial source/drain regions 62U may be selected from the same candidate group of materials for forming lower source/drain regions 62L, depending on the desired conductivity type of upper epitaxial source/drain regions 62U.

The conductivity type of the upper epitaxial source/drain regions 62U may be opposite the conductivity type of the lower epitaxial source/drain regions 62L. Alternatively stated, the upper epitaxial source/drain regions 62U may be oppositely doped from the lower epitaxial source/drain regions 62L. The upper epitaxial source/drain regions 62U may be in-situ doped, and/or may be implanted, with an n-type or p-type dopant.

Next, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the dummy gate stacks 42 are coplanar (within process variations). The planarization process may remove masks 40, or leave hard masks 40 unremoved.

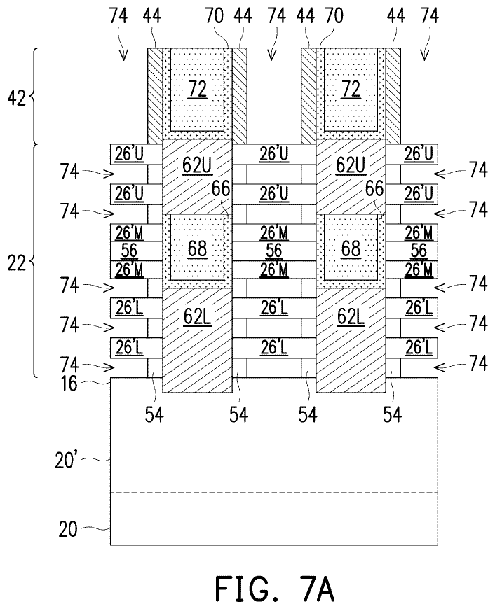

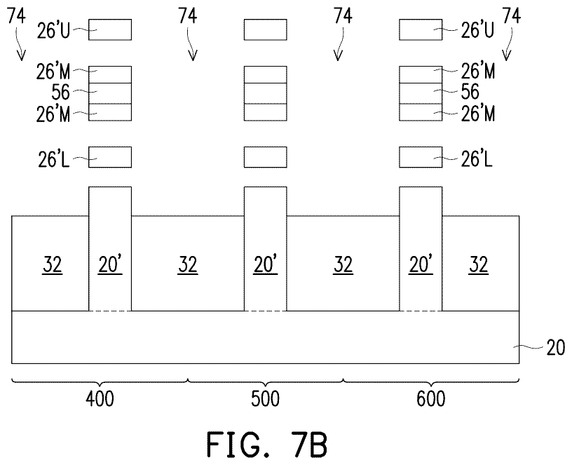

The dummy gate stacks 42 are then removed in one or more etching processes, so that recesses 74 are formed, as shown in FIGS. 7A and 7B. The respective process is illustrated as process 204 in the process flow 200 as shown in FIG. 24. Each of recesses 74 exposes and/or overlies portions of multi-layer stacks 22′.

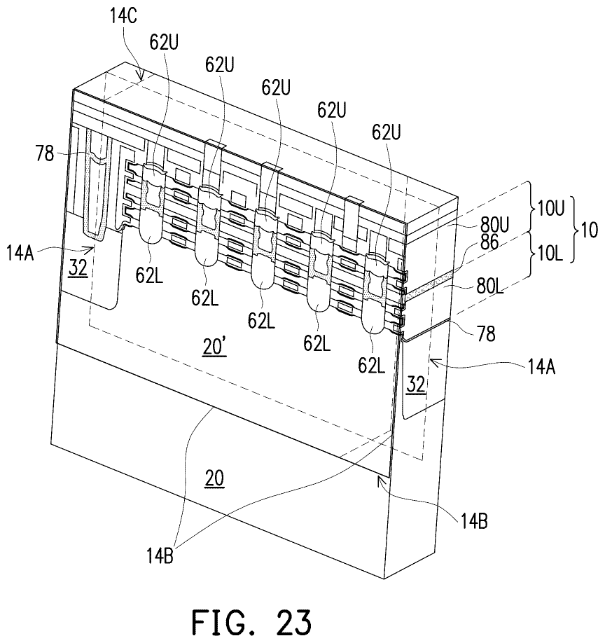

The cross-section as shown in FIG. 7B may be the vertical cross-section A-A′ as shown in FIG. 1. In FIG. 7B, three device regions 400, 500, and 600 are illustrated. Each of the device regions 400, 500, and 600 is for forming a CFET including an upper FET and a lower FET. Each of the device regions 400, 500, and 600 may also be obtained from a vertical cross-section 14A-14A as shown in FIG. 23, which cross-section 14-14A cuts through the metal gates to be formed.

The remaining portions of the dummy nanostructures 24′A (FIG. 6) are then removed through etching, so that recesses 74 extend between the semiconductor nanostructures 26′. In the etching process, the dummy nanostructures 24′A are etched at a faster rate than the semiconductor nanostructures 26′, the dielectric isolation layers 56, and the inner spacers 54. The etching may be isotropic. For example, when the dummy nanostructures 24′A are formed of silicon-germanium, and the semiconductor nanostructures 26′ are formed of silicon, the etch process may include a wet etch process using tetramethylammonium hydroxide (TMAH), ammonium hydroxide (NH₄OH), or the like.

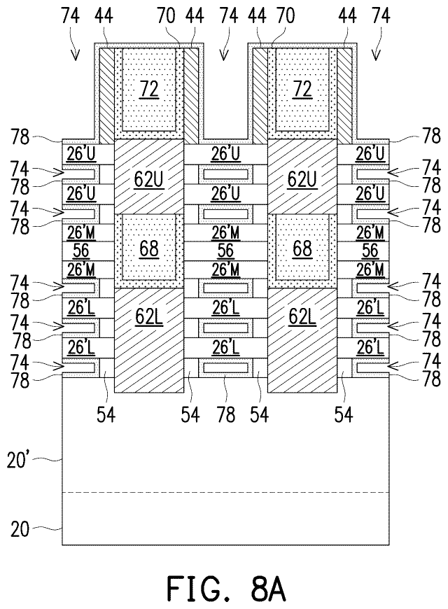

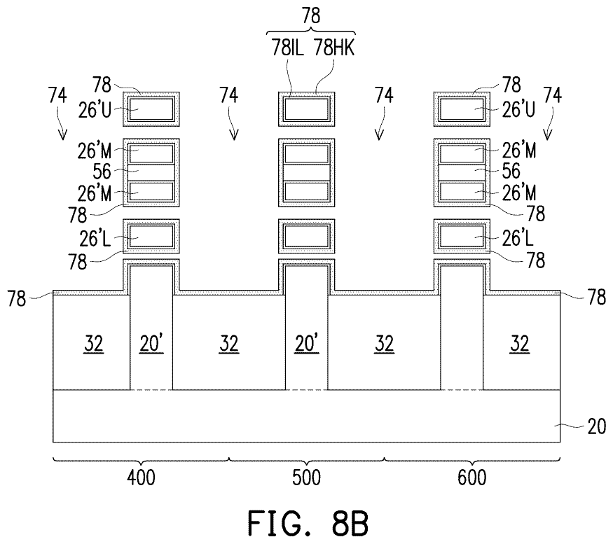

FIGS. 8A, 8B, 9-13, 14A, 14B, and 14C illustrate the details for forming gate dielectrics 78 and gate electrodes 80 (including 80U and 80L) in accordance with some embodiments. In FIGS. 8A and 8B, gate dielectrics 78 are formed in recesses 74, and are formed on the exposed semiconductor nanostructures 26′. The respective process is illustrated as process 206 in the process flow 200 as shown in FIG. 24. The gate dielectrics 78 are formed on the exposed surfaces of the exposed features including the semiconductor nanostructures 26′ and the gate spacers 44. The gate dielectrics 78 wrap around all (e.g., four) sides of the semiconductor nanostructures 26′.

Each of the gate dielectrics 78 may include an interfacial layer 78IL, which is shown but not marked separately. The interfacial layer 78IL may include an oxide such as silicon oxide or a metal oxide, a silicate such as a metal silicate, combinations thereof, multi-layers thereof, or the like. The interfacial layer 78IL may be formed of a thermal oxidation process and/or a deposition process.

Each gate dielectric 78 may also include a high-k dielectric layers 78HK over the interfacial layer, which have a high dielectric constant (high-k) value greater than, for example, about 7.0, about 21, or higher. The high-k dielectric layer 78HK may be formed of or comprise a metal oxide or a silicate of a metal selected from hafnium, zirconium, barium, titanium, lead, and combinations thereof. The formation methods of the high-k dielectric layer 78HK may be selected from Molecular-Beam Deposition (MBD), ALD, PECVD, and the like. High-k dielectric layers 78HK may have a thickness in the range between about 1 nm and about 5 nm. The gate dielectrics 78 in device regions 400, 500, and 600 may be formed in common processes.

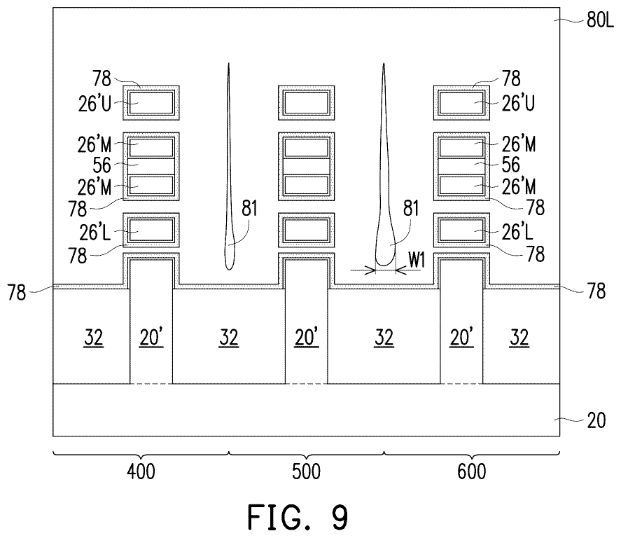

Referring to FIG. 9, lower gate electrode 80L is formed. The respective process is illustrated as process 208 in the process flow 200 as shown in FIG. 24. In accordance with some embodiments, lower gate electrode 80L includes a work function layer, and may also include other layers such as a capping layer under the work function layer, a blocking layer over the work function layer, and may or may not include a metal-filling layer over the blocking layer. The formation of the lower gate electrode 80L may include deposition processes such as ALD, Metal-organic Chemical Vapor Deposition, (MOCVD), PECVD, or the like. After the depositions of the layers of the lower gate electrode 80L, a planarization process is performed to level the top surface of the lower gate electrode 80L.

In accordance with some embodiments, the capping layer and the blocking layer may comprise TiN or TiSiN, the material of the work function layer depends on whether the lower FETs are NFET or PFETs. For example, when the lower FETs are NFETs, the work function layer may include TiAIN, TiAl, TiN, tungsten, or the like. When the lower FETs are PFETs, the work function layer may include TiN, TaN, tungsten, or the like.

In accordance with some embodiments, the lower gate electrode 80L may (or may not) include seams 81. The bottoms of seams 81 are close to the bottom of the lower gate electrode 80L. In accordance with some embodiments, the width W1 of the seams 81 may be in the range between about 1 nm and about 5 nm.

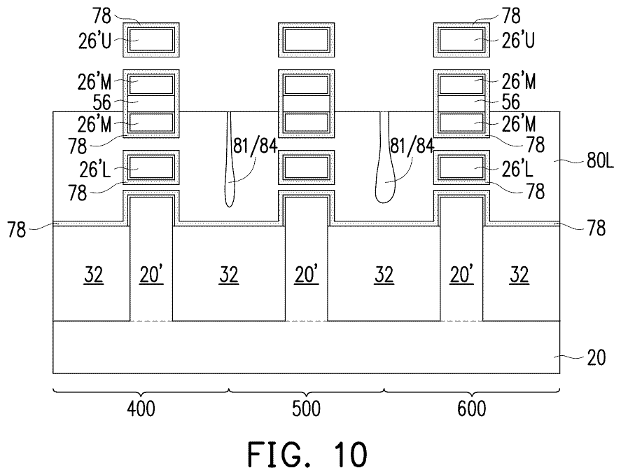

Referring to FIG. 10, an etch back process is performed to recess the lower gate electrode 80L. The respective process is illustrated as process 210 in the process flow 200 as shown in FIG. 24. The top surface of the remaining lower gate electrode 80L is lower than the top surface of the upper one of the middle semiconductor nanostructures 26′M, and higher than the bottom surface of the lower one of the middle semiconductor nanostructures 26′M.

The etch back process may be performed using a dry etching process or a wet etching process. For example, when dry etching is adopted, chlorine (Cl₂) may be used as an etching gas, while a carrier gas such as Ar, N₂, or the like may be used. The seams 81 may be exposed as a result of the etching process. In accordance with some embodiments, the etch back process may be performed by adding some by-product generating gases such as SiCl₄, O₂, CH₄, N₂, BCl₃, and/or the like. Accordingly, by-product 84 is generated, and fills seams 81 during the etch back process. Depending on the gases added, the by-product 84 may comprise an inorganic material such as SiCO, SiCN, BN, or the like, a polymeric material such as polymeric Carbon nitride (CN), or combinations thereof. The by-product 84 may also be a dielectric material. The generated by-product that fills seams 81 is also referred to as by-product regions 84.

In accordance with some embodiments, the by-product regions 84 fully occupy seams 81. In accordance with alternative embodiments, the by-product regions 84 partially occupy seams 81. For example, the by-product regions 84 may occupy the lower parts of seams 81, while leaving upper parts unfilled. The by-product regions 84 may also form a conformal liner of the sidewalls of seams 81, while leaving the center portions of seams 81 unfilled. Throughout the description, the seams 81 and the by-product regions 84 are referred to as regions 81/84, which means the corresponding regions are seams 81 in the form or air gaps and/or the by-product regions 84.

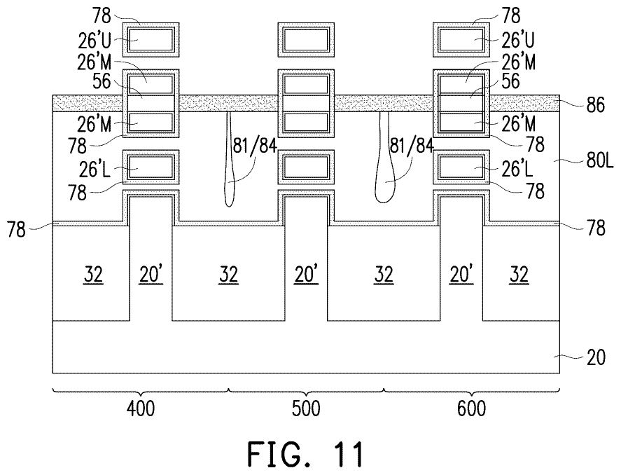

FIG. 11 illustrates the formation of gate isolation layer 86. The respective process is illustrated as process 212 in the process flow 200 as shown in FIG. 24. In accordance with some embodiments, gate isolation layer 86 comprises a dielectric material such as SiO, SiN, SiCN, SiOC, SiOCN, SiON, or the like. The formation process may include depositing the gate isolation layer 86 through a deposition process such as an ALD process, a CVD process, a PVD process, or the like, planarizing the top surface of the gate isolation layer 86 (for example, through CMP or mechanical grinding), and etching back the dielectric layer. The resulting gate isolation layer 86 has a top surface lower than the top surface of the upper one of the middle semiconductor nanostructures 26′M.

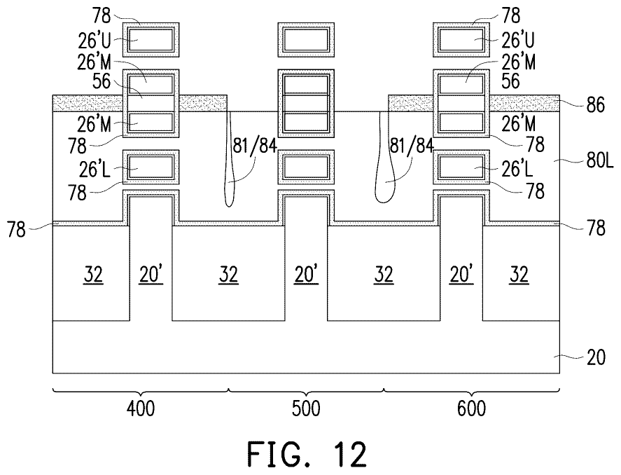

FIG. 12 illustrates the optional patterning of gate isolation layer 86, which may be performed by forming an etching mask (such as a patterned photoresist, not shown), and etching gate isolation layer 86. The respective process is illustrated as process 214 in the process flow 200 as shown in FIG. 24. After the patterning of gate isolation layer 86, regions 81/84 may be revealed, covered by gate isolation layer 86, or with some portions of gate isolation layer 86 revealed, and other portions of gate isolation layer 86 covered by gate isolation layer 86.

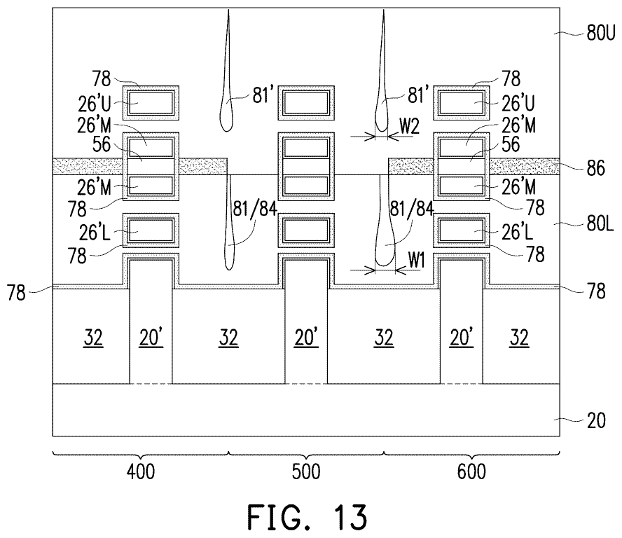

FIG. 13 illustrates the formation of upper gate electrode 80U in accordance with some embodiments. The respective process is illustrated as process 216 in the process flow 200 as shown in FIG. 24. The formation of upper gate electrode 80U may include depositing a plurality of conductive layers, and performing a planarization process. The structure and the materials of the upper gate electrode 80U may be found referring to the discussion of lower gate electrode 80L, except that the corresponding upper FETs may have a conductivity type opposite to that of the lower FETs, and the material of the work function layer in the upper gate electrode 80U is selected to suit to the conductivity type of the upper FETs.

In accordance with some embodiments, seams 81′ are formed in the upper gate electrode 80U. The seams 81′, when formed, may have width W2, which may be smaller than the width W1 (FIG. 9). In accordance with alternative embodiments, seams 81′ are not formed.

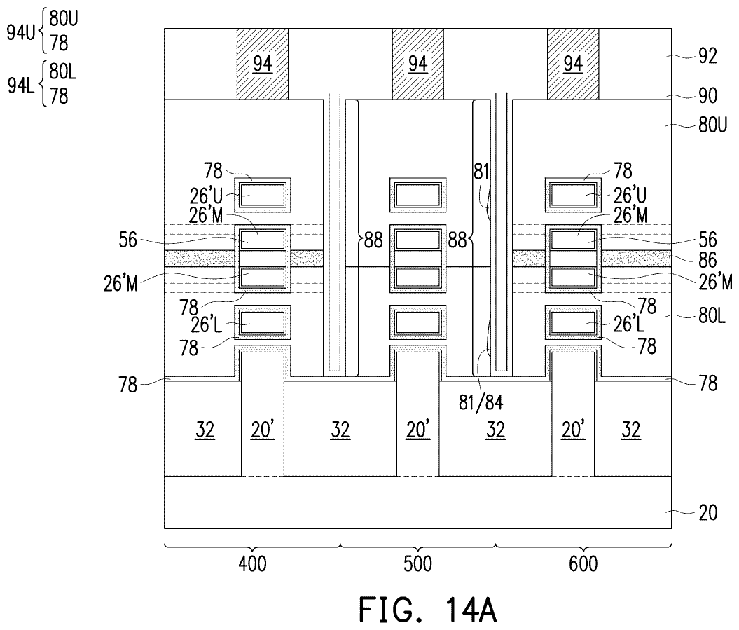

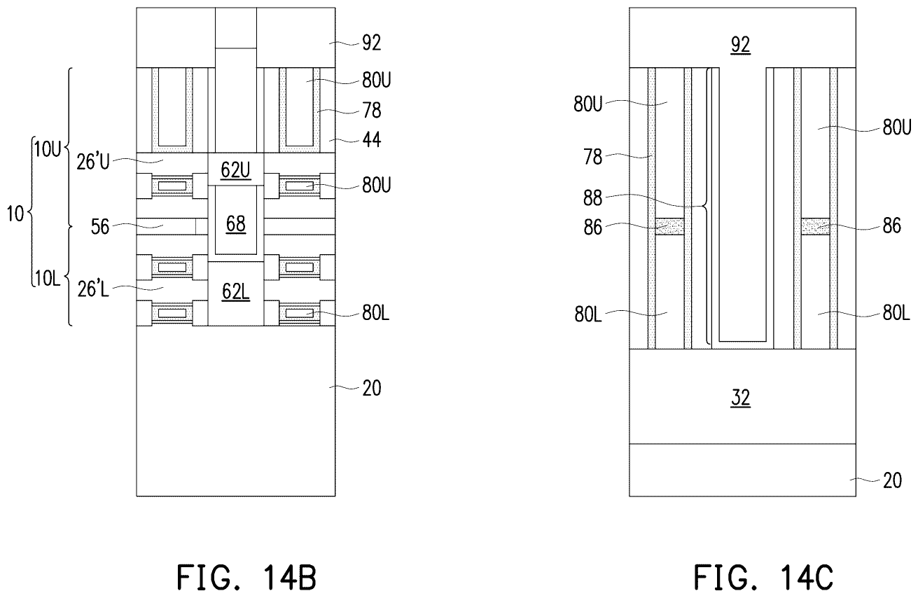

FIG. 14A illustrates the formation of isolation regions 88, which electrically and physically isolate the gate electrodes 80L and 80U in device regions 400, 500, and 600 from each other. The respective process is illustrated as process 218 in the process flow 200 as shown in FIG. 24. The formation process may include etching upper gate electrode 80U and lower gate electrode 80L to form an opening, until the underlying gate dielectric 78 is exposed. The gate dielectric 78 may be etched to reveal the underlying STI region 32, or may not be etched. In a subsequent process, dielectric materials are filled into the opening to form the gate isolation regions 88.

In accordance with some embodiments, after the formation of a gate isolation region 88, the respective region 81/84 is fully removed. In accordance with alternative embodiments, after the formation of a gate isolation region 88, the respective region 81/84 is partially removed, and partially remaining, as shown in FIG. 14A. In accordance with yet alternative embodiments, an entirety of a region 81/84 remains since the corresponding gate isolation region 88 is not formed (while other gate isolation regions 88 may still be formed).

In accordance with some embodiments, the isolation regions 88 may be formed simultaneously as the formation of Contact Etch stop Layer (CESL 90) and Inter-Layer Dielectric (ILD) 92, and the materials of the CESL 90 and ILD 92 filling the openings form the isolation regions. In other embodiments, isolation regions 88 are formed by processes separating from the formation of the CESL 90 and ILD 92. In accordance with some embodiments, the CESL 90 may be formed of a nitride such as SiN, SiC, SiOCN, or the like, while the ILD 92 may be formed of an oxide such as SiO, SiOC, SiOCN, or the like. Gate contact plugs 94 are formed to extend into ILD 92 to electrically connect to upper gate electrode 80U. The electrical connection to the lower gate electrode 80L is also formed, and is not illustrated.

Throughout the description, the gate electrodes 80L and the underlying gate dielectrics 78 are collectively referred to as gate stacks 94L, and the gate electrodes 80U and the underlying gate dielectrics 78 are collectively referred to as gate stacks 94U. CFET 10 is thus formed, which includes lower FET 10L (including gate stacks 94L and source/drain regions 62L (FIG. 14B)) and upper FET 10U (including gate stacks 94U and source/drain regions 62U (FIG. 14B)).

The gate isolation layer 86 may be at the same level as the dielectric isolation layers 56. In accordance with alternative embodiments, as shown in FIG. 14A, the gate isolation layer 86 may have its top surface level with the top surface of the upper one of the middle semiconductor nanostructures 26′M, and the corresponding gate isolation layer 86 is marked by dashed lines 86′. In accordance with alternative embodiments, the gate isolation layer 86 may have its bottom surface level with the bottom surface of the lower one of the middle semiconductor nanostructures 26′M, and the corresponding gate isolation layer 86 is marked by dashed lines 86″. Gate isolation layer 86 may also be at any position between the positions marked by dashed lines 86′ and 86″.

FIG. 23 illustrates a perspective view of CFET 10 in accordance with some embodiments. Source/drain regions 62L and 62U, gate electrodes 80L and 80U, gate isolation layer 86, STI regions 32, etc., are marked.

The cross-sectional view as shown in FIG. 14A is obtained from the vertical cross-section 14A-14A as shown in FIG. 23 (and the vertical cross-section A-A′ shown in FIG. 1), which cross-section cuts through the metal gate electrodes. FIG. 14B illustrates a vertical cross-section 14B-14B shown in FIG. 23 (and the vertical cross-section B-B′ shown in FIG. 1), which cross-section cuts through the nanostructures 26U and 26L (channel regions) and source/drain regions 62U and 62L. FIG. 14C illustrates a vertical cross-section 14C-14C shown in FIG. 23, which cross-section cuts through the STI region 32 and the gate isolation region 88 for separating neighboring gate electrodes 80U and 80L from each other.

As shown in FIG. 14A, in some embodiments, regions 81/84 may be fully removed in the formation of gate isolation regions 88. Some or all of the regions 81/84 may have some portions remaining, as also shown in FIG. 14A, depending on the widths of regions 81/84 and the width of gate isolation regions 88. In accordance with some embodiments, some of the gate isolation regions 88 are not formed, and hence the regions 81/84 as shown in FIG. 13 will remain in the final structure.

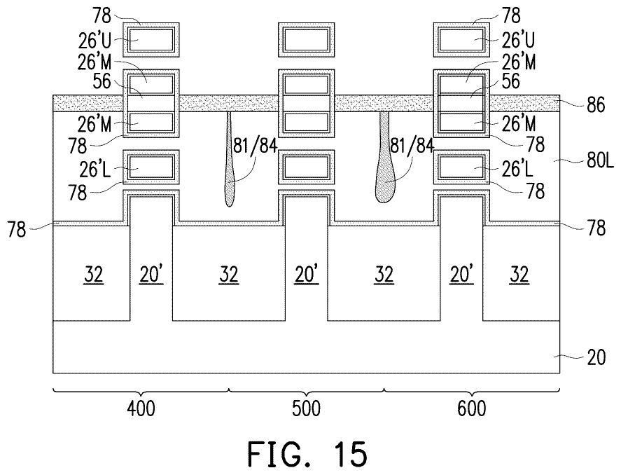

FIGS. 15 through 22 illustrate the structure formed in accordance with alternative embodiments. It is appreciated that the structures formed in accordance with these embodiments and the structure shown in FIGS. 14A, 14B, and 14C may co-exist in the same device die and the same device wafer, and are formed sharing same formation processes.

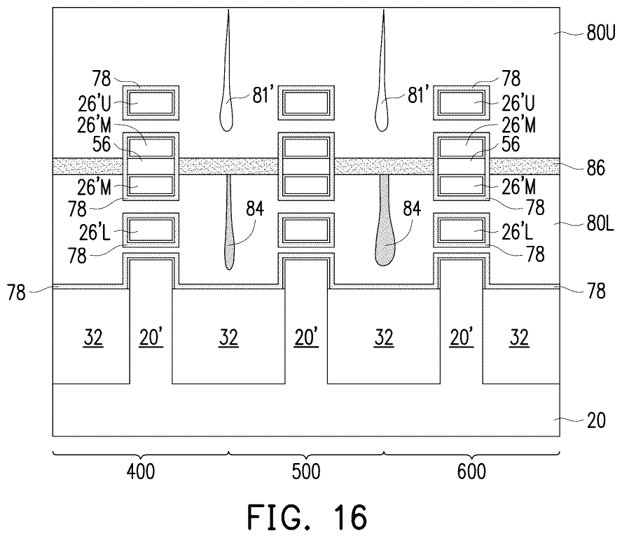

FIGS. 15 and 16 illustrate the formation of the lower gate electrode 80L, gate isolation layer 86, and upper gate electrode 80U in accordance with some embodiments. The by-product regions 84 are illustrated. By forming by-product regions 84, it is easier for gate isolation layer 86 to seal the underlying seams 81.

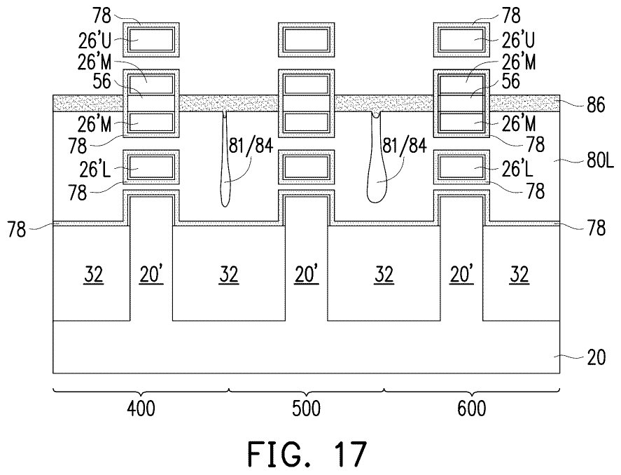

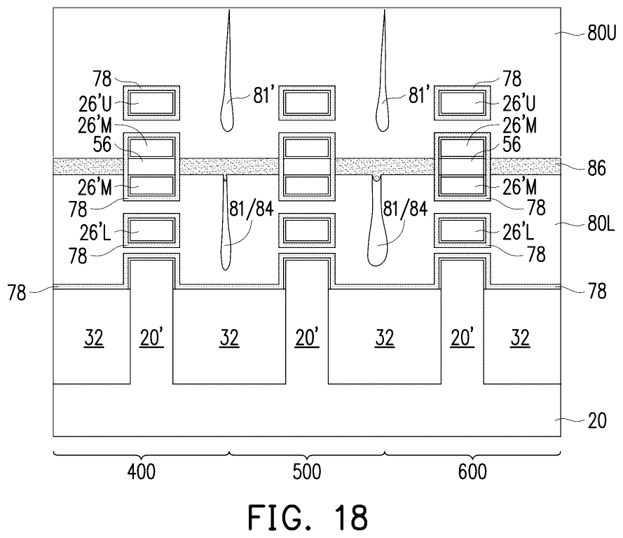

FIGS. 17 and 18 illustrate the formation of the lower gate electrode 80L, gate isolation layer 86, and upper gate electrode 80U in accordance with alternative embodiments. The illustrated seams 81 are not filled with by-product regions 84, or may be partially filled with by-product regions 84, for example, with the lower portions filled. Alternatively, the product regions 84 may be formed as conformal liners. This structure may be resulted when no by-product generating gas is added in the etch back process of the lower gate electrode 80L. Alternatively, this structure may be resulted when that the by-products are generated, but does not fill into the illustrated seams 81, or fill with inadequate amount. Gate isolation layer 86 thus will have some portions extending into and filling the upper portions of the underlying seams 81.

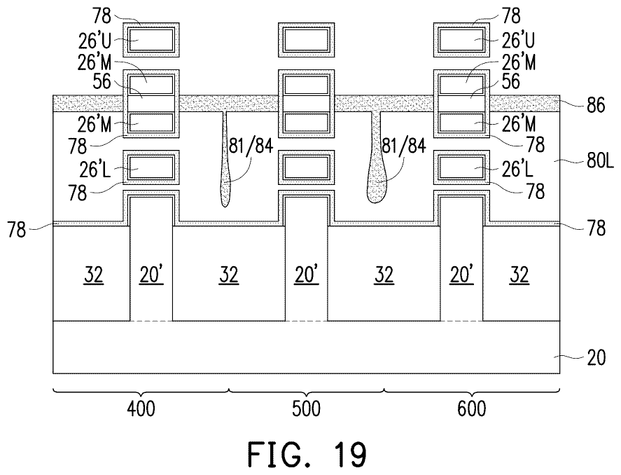

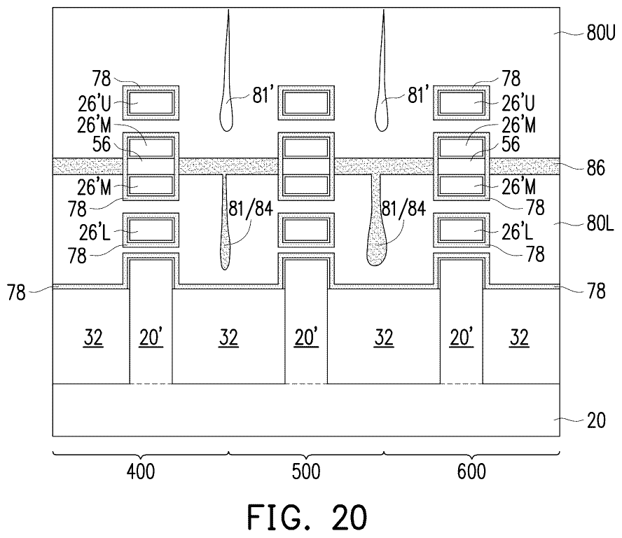

FIGS. 19 and 20 illustrate the formation of the lower gate electrode 80L, gate isolation layer 86, and upper gate electrode 80U in accordance with yet alternative embodiments. The illustrated seams 81 are not filled with by-product regions 84, or may be partially filled, for example, with the lower portions filled. In accordance with some embodiments, gate isolation layer 86 is deposited through a bottom-up deposition process. Accordingly, gate isolation layer 86 will fill the remaining underlying seams 81. Seams 81 may or may not include the by-products, and if the by-products are generated, the remaining seams 81 unfilled by the by-products will be fully filled by gate isolation layer 86.

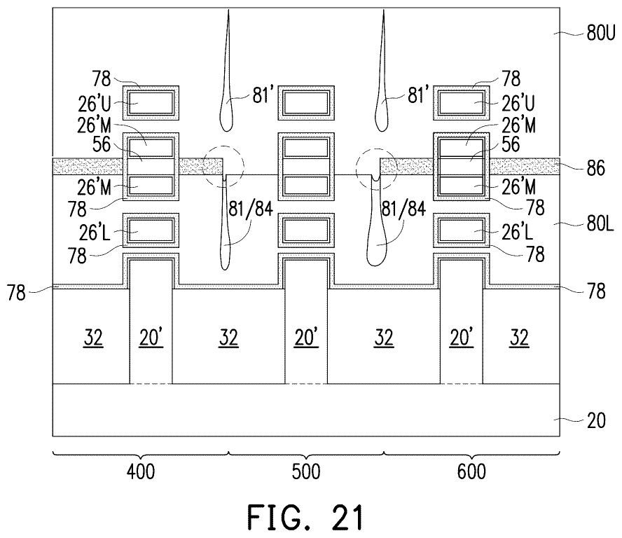

FIG. 21 illustrates the formation of the lower gate electrode 80L, gate isolation layer 86, and upper gate electrode 80U in accordance with some embodiments. The gate isolation layer 86 is patterned, and the underlying seams 81 may be revealed again. Accordingly, the upper gate electrode 80U will seal the underlying seams 81. Furthermore, the upper gate electrode 80U may extend into the underlying seams 81.

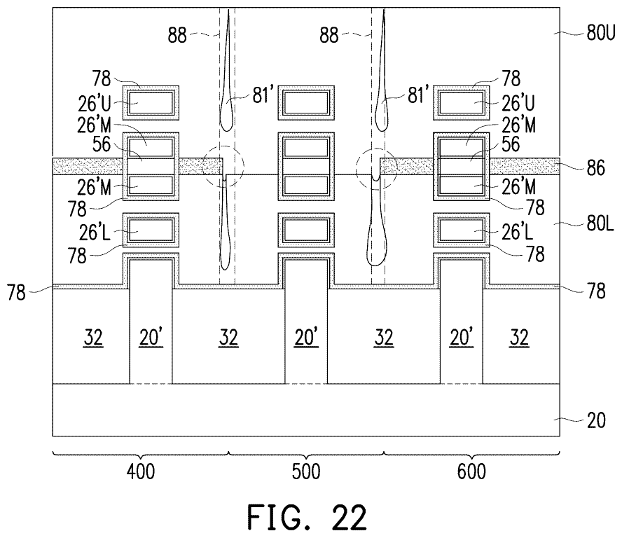

In accordance with some embodiments, the structure shown in FIG. 22 exists in the final structure that is shown in FIG. 23. In accordance with alternative embodiments, after the formation of the structure shown in FIG. 22, the process shown in FIG. 14A is performed, and gate isolation regions 88 are formed, which are illustrated by dashed lines.

The embodiments of the present disclosure have some advantageous features. By forming a horizontal gate isolation layer between the upper gate electrode and the lower gate electrode in a CFET structure, the upper gate electrode and the lower gate electrode are electrically isolated from each other. Process may be adjusted to fill the seams that may be formed in the lower gate electrode.

In accordance with some embodiments of the present disclosure, a method comprises forming a lower semiconductor region; forming an upper semiconductor region overlapping the lower semiconductor region; forming a lower gate dielectric and an upper gate dielectric on the lower semiconductor region and the upper semiconductor region, respectively; forming a lower gate electrode on the lower gate dielectric and the upper gate dielectric; etching back the lower gate electrode; forming a gate isolation layer on the lower gate electrode that has been etched back; and forming an upper gate electrode over the gate isolation layer, wherein the upper gate electrode is on the upper gate dielectric.

In an embodiment, the method further comprises patterning the gate isolation layer. In an embodiment, the forming the gate isolation layer comprises depositing a dielectric layer; planarizing the dielectric layer; and etching back the dielectric layer, wherein a remaining portion of the dielectric layer forms the gate isolation layer. In an embodiment, a seam is formed in the lower gate electrode, and wherein after the lower gate electrode is etched back, the seam is revealed.

In an embodiment, during the etching back the lower gate electrode, a by-product is generated to at least partially fill the seam. In an embodiment, in the etching back the lower gate electrode, a silicon-containing process gas is added, and the by-product comprises a silicon-containing dielectric. In an embodiment, the by-product fully fills the seam. In an embodiment, the method further comprises etching the lower gate electrode and the upper gate electrode; and filling a dielectric region in spaces left by the etched lower gate electrode and the etched the upper gate electrode.

In an embodiment, a seam is formed in the lower gate electrode, and wherein the gate isolation layer at least partially fills the seam. In an embodiment, the gate isolation layer fully fills the seam. In an embodiment, the lower semiconductor region comprises a first semiconductor nanostructure, and the upper semiconductor region comprises a second semiconductor nanostructure, and the method further comprises forming a first source/drain region joining to the first semiconductor nanostructure; and forming a second source/drain region joining to the second semiconductor nanostructure.

In accordance with some embodiments of the present disclosure, a structure comprises a lower transistor comprising a first semiconductor region; a first gate dielectric on the first semiconductor region; and a lower gate electrode on the first gate dielectric; and an upper transistor comprising a second semiconductor region overlapping the first semiconductor region; a second gate dielectric on the second semiconductor region; and an upper gate electrode on the second gate dielectric; and a gate isolation layer overlying and contacting the lower gate electrode, wherein the gate isolation layer is further underlying and contacting the upper gate electrode. In an embodiment, the lower transistor and the upper transistor have opposite conductivity types.

In an embodiment, the structure further comprises an isolation region comprising a sidewall contacting edges of the lower gate electrode, the gate isolation layer, and the upper gate electrode. In an embodiment, the lower gate electrode further comprises a silicon-containing dielectric region therein. In an embodiment, the lower gate electrode further comprises a seam filled with a same material as the gate isolation layer. In an embodiment, the lower gate electrode further comprises a seam as an air gap.

In accordance with some embodiments of the present disclosure, a structure comprises a first CFET structure comprising a first lower FET comprising a first lower gate electrode; a first upper FET comprising a first upper gate electrode overlapping the first lower gate electrode; and a first gate isolation layer between and joining to the first lower gate electrode and the first upper gate electrode; a second CFET structure comprising a second lower FET comprising a second lower gate electrode; and a second upper transistor comprising a second upper gate electrode overlapping the second lower gate electrode; and an isolation region comprising a first sidewall contacting first edges of the first lower gate electrode and the first upper gate electrode; and a second sidewall contacting second edges of the second lower gate electrode and the second upper gate electrode. In an embodiment, the structure further comprises a second gate isolation layer between and joining to the second lower gate electrode and the second upper gate electrode. In an embodiment, the second lower gate electrode physically contacts the second upper gate electrode.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a lower semiconductor region;
forming an upper semiconductor region overlapping the lower semiconductor region;
forming a lower gate dielectric and an upper gate dielectric on the lower semiconductor region and the upper semiconductor region, respectively;
forming a lower gate electrode on the lower gate dielectric and the upper gate dielectric;
etching back the lower gate electrode;
forming a gate isolation layer on the lower gate electrode that has been etched back; and
forming an upper gate electrode over the gate isolation layer, wherein the upper gate electrode is on the upper gate dielectric; and
patterning the gate isolation layer, wherein the forming the gate isolation layer comprises:
depositing a dielectric layer;
planarizing the dielectric layer; and
etching back the dielectric layer, wherein a remaining portion of the dielectric layer forms the gate isolation layer.
